(19) United States
(12) Patent Application Publication
(10) Pub. No.: US 2026/0143632 A1
(43) Pub. Date: May 21, 2026

(54) LIQUID COOLING ASSEMBLY

(71) Applicants: INVENTEC (PUDONG) TECHNOLOGY CORPORATION, Shanghai (CN); INVENTEC CORPORATION, Taipei City (TW)

(72) Inventors: Kai-Yang TUNG, Taipei City (TW); Hung-Ju CHEN, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/213,660

(22) Filed: May 20, 2025

(30) Foreign Application Priority Data
Nov. 18, 2024 (CN) 202411651813.7

(51) Int. Cl. H05K 7/20

(52) U.S. Cl. CPC H05K 7/20272; H05K 7/20254

(57) ABSTRACT

A liquid cooling assembly includes a liquid delivery component, a liquid absorbing component and a liquid block cover. The liquid delivery component includes a housing, an inlet joint and an outlet joint. The housing includes a liquid collecting recess, and the inlet joint and the outlet joint are disposed on the housing and at least partially located in the liquid collecting recess. The liquid absorbing component is mounted in the liquid collecting recess of the housing and partially protruding out of the liquid collecting recess. The liquid block cover is disposed on the housing and encloses the liquid absorbing component along with the housing.

### CROSS-REFERENCE TO RELATED APPLICATIONS

This non-provisional application claims priority under 35 U.S.C. § 119(a) on Patent Application No(s). 202411651813.7 filed in China, on November 18, 2024, the entire contents of which are hereby incorporated by reference.

### BACKGROUND OF THE INVENTION

### Technical Field of the Invention

The invention relates to a liquid cooling assembly.

### Description of the Related Art

To prevent components in liquid cooling systems from leaking and damaging surrounding electronic components, liquid absorbing materials have been placed on these components to temporarily store leaked liquid, avoiding direct contact of the leaked liquid with nearby electronic components.

However, the storage capacity of the liquid absorbing material is limited, and the size of the liquid absorbing component is also constrained, making it difficult to increase the storage capacity to delay the time for personnel to handle the leak. In light of this, researchers in the field are actively working to address the aforementioned issue.

### SUMMARY OF THE INVENTION

The invention provides a liquid cooling assembly which can delay the time for personnel to handle the leak as long as possible.

One embodiment of the invention provides a liquid cooling assembly. The liquid cooling assembly includes a liquid delivery component, a liquid absorbing component and a liquid block cover. The liquid delivery component includes a housing, an inlet joint and an outlet joint. The housing includes a liquid collecting recess, and the inlet joint and the outlet joint are disposed on the housing and at least partially located in the liquid collecting recess. The liquid absorbing component is mounted in the liquid collecting recess of the housing and partially protruding out of the liquid collecting recess. The liquid block cover is disposed on the housing and encloses the liquid absorbing component along with the housing.

Another embodiment of the disclosure provides a liquid cooling assembly. The liquid cooling assembly includes a liquid delivery component, a liquid absorbing component and a liquid guiding component. The liquid delivery component includes a housing, an inlet joint and at least one outlet joint, and the inlet joint and the outlet joint are disposed on the housing. The liquid absorbing component is disposed on the housing and corresponds to the inlet joint and the outlet joint. The liquid guiding component is connected to the liquid absorbing component.

According to the liquid cooling assembly as discussed in the above embodiment, the liquid absorbing component is mounted in the liquid collecting recess of the housing and partially protrudes out of the liquid collecting recess, the liquid block cover is disposed on the housing, and the liquid block cover and the housing together enclose the liquid absorbing component. This configuration allows the liquid absorbing component, even when protruding out of the liquid collecting recess, to retain the leaked liquid, absorbed from the inlet joint or the outlet joint, in the liquid block cover. As a result, more leaked liquid can be stored, such that the time for personnel to perform maintenance can be delayed as long as possible.

On the other hand, the liquid absorbing component is disposed on the housing of the liquid delivery component and corresponds to the inlet joint and the outlet joints, and the liquid guiding component is connected to the liquid absorbing component. By this configuration, the liquid guiding component can guide and deliver the leaked liquid absorbed by the liquid absorbing component from the inlet joint or the outlet joints, allowing the liquid absorbing component to continue absorb the leaked liquid. As a result, the time for personnel to perform maintenance can be delayed as long as possible.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a perspective view of a liquid cooling assembly according to a first embodiment of the invention;

FIG. 2 is an exploded view of the liquid cooling assembly in FIG. 1;

FIG. 3 is a cross-sectional view of the liquid cooling assembly in FIG. 1;

FIG. 4 is a cross-sectional view of the liquid cooling assembly in FIG. 3 when leakage occurs;

FIG. 5 is a perspective view of a liquid cooling assembly according to a second embodiment of the invention;

FIG. 6 is another perspective view of the liquid cooling assembly in FIG. 5; and

FIG. 7 is a partial cross-sectional view of the liquid cooling assembly in FIG. 5.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present invention, such as technical and scientific terms, have its own meanings and can be comprehended by those skilled in the art, unless the terms are additionally defined in the present invention. That is, the terms used in the following paragraphs should be read on the meaning commonly used in the related fields and will not be overly explained, unless the terms have a specific meaning in the present invention.

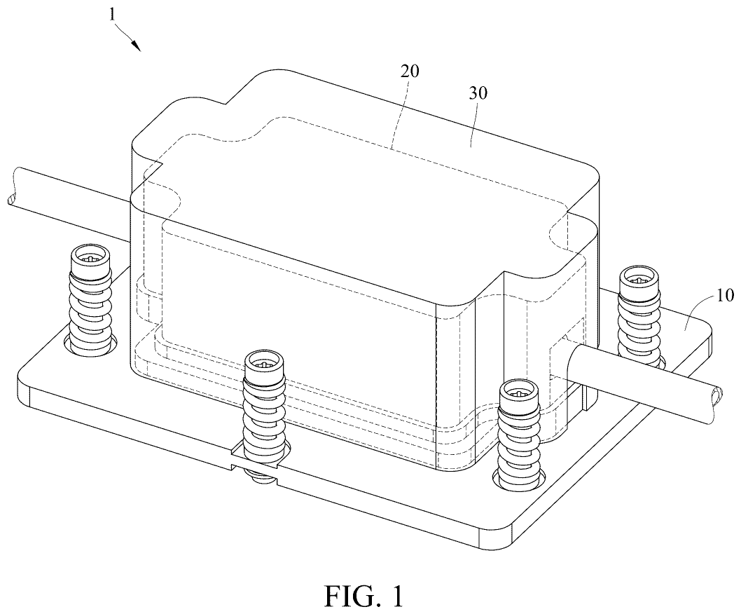

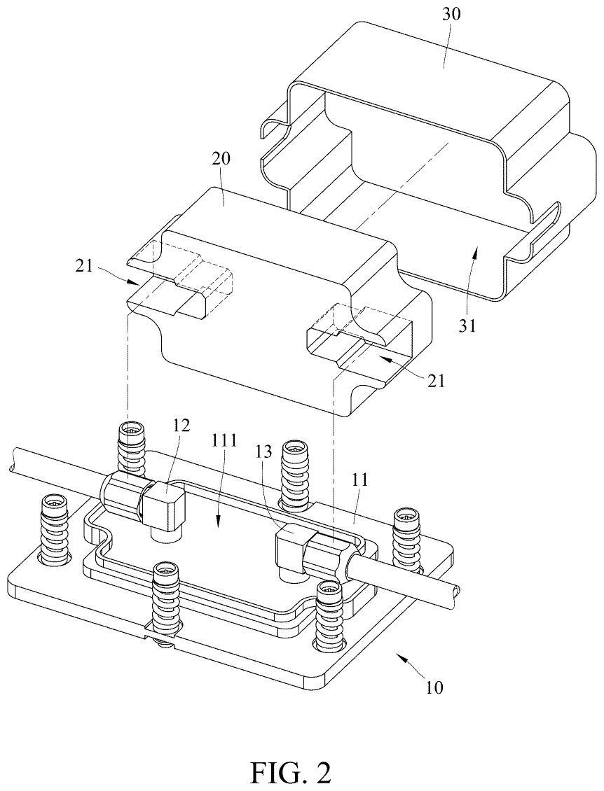

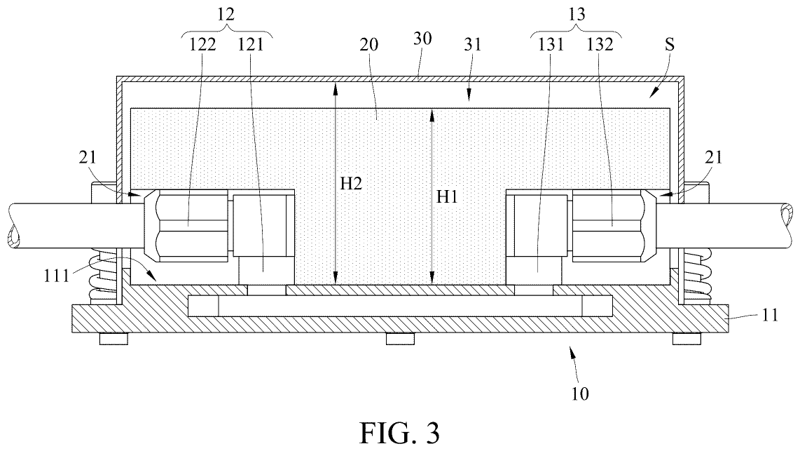

Referring to FIGS. 1 to 3, FIG. 1 is a perspective view of a liquid cooling assembly according to a first embodiment of the invention, FIG. 2 is an exploded view of the liquid cooling assembly in FIG. 1, and FIG. 3 is a cross-sectional view of the liquid cooling assembly in FIG. 1. In this embodiment, the liquid cooling assembly 1 includes a liquid delivery component 10, a liquid absorbing component 20 and a liquid block cover 30. The liquid cooling assembly 1 is, for example, suitable for use in a server.

The liquid delivery component 10, for example but not limited to, a cold plate. The liquid delivery component 10 includes a housing 11, an inlet joint 12 and an outlet joint 13. The housing 11 includes a liquid collecting recess 111. The inlet joint 12 includes a housing assembling portion 121 and a pipe assembling portion 122 connected to each other. The housing assembling portion 121 and the pipe assembling portion 122 of the inlet joint 12 are, for example but not limited to, perpendicular to each other. The outlet joint 13 includes a housing assembling portion 131 and a pipe assembling portion 132 connected to each other. The housing assembling portion 131 and the pipe assembling portion 132 of the outlet joint 13 are, for example but not limited to, perpendicular to each other. The housing assembling portion 121 of the inlet joint 12 and the housing assembling portion 131 of the outlet joint 13 are partially located in the liquid collecting recess 111 and are connected to the housing 11. The pipe assembling portion 122 of the inlet joint 12 and the pipe assembling portion 132 of the outlet joint 13 are located outside the liquid collecting recess 111.

The liquid absorbing component 20 is mounted in the liquid collecting recess 111 of the housing 11 and partially protrudes out of the liquid collecting recess 111. The liquid absorbing component 20 includes two avoidance recesses 21, the inlet joint 12 and the outlet joint 13 are respectively accommodated in the two avoidance recesses 21. It should be noted that the two avoidance recesses 21 are optional structures. In other embodiments, the liquid absorbing component may be designed without the avoidance recesses, in a shape that does not interfere with the inlet joint and the outlet joint.

The liquid block cover 30 is disposed on the housing 11 and encloses the liquid absorbing component 20 along with the housing 11. For example, the liquid block cover 30 includes an accommodation recess 31, and the accommodation recess 31 and the liquid collecting recess 111 together form a liquid storage chamber S. The liquid absorbing component 20 is accommodated in the liquid storage chamber S.

In the embodiment, the liquid absorbing component 20 is made of a liquid-absorbent and expandable material. For example, the liquid absorbing component 20 may be a polyvinyl alcohol foam. The liquid absorbing component 20 includes an initial state and a saturated state. As shown in FIG. 3, when the liquid absorbing component 20 is in the initial state, a height H1 of the liquid absorbing component 20 is less than a height H2 of the liquid storage chamber S.

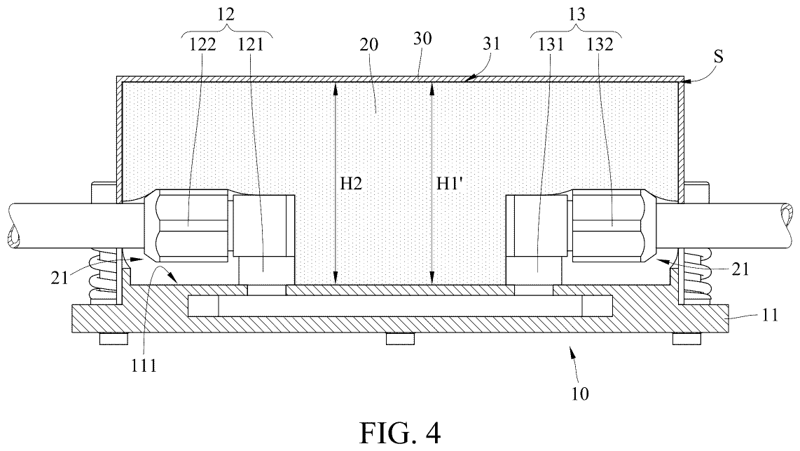

Then, referring to FIG. 4, FIG. 4 is a cross-sectional view of the liquid cooling assembly in FIG. 3 when leakage occurs.

When leakage occurs at the inlet joint 12 or the outlet joint 13 of the liquid delivery component 10, the leaked liquid is absorbed by the liquid absorbing component 20, causing the liquid absorbing component 20 to expand and switch from the initial state to the saturated state. At this moment, a height H1′ of the liquid absorbing component 20 is equal to the height H2 of the liquid storage chamber S. In other words, the liquid absorbing component 20 fills the entire liquid storage chamber S.

In this embodiment, the liquid absorbing component 20 is mounted in the liquid collecting recess 111 of the housing 11 and partially protrudes out of the liquid collecting recess 111, the liquid block cover 30 is disposed on the housing 11, and the liquid block cover 30 and the housing 11 together enclose the liquid absorbing component 20. This configuration allows the liquid absorbing component 20, even when protruding out of the liquid collecting recess 111, to retain the leaked liquid, absorbed from the inlet joint 12 or the outlet joint 13, in the liquid block cover 30. As a result, more leaked liquid can be stored, such that the time for personnel to perform maintenance can be delayed as long as possible.

It should be noted that the liquid absorbing component 20 is not limited to being made of an expandable material. In other embodiments, the liquid absorbing component may be made of a non-expandable material. In such a case, before the liquid absorbing component absorbs the leaked liquid, the height of the liquid absorbing component may be equal to the height of the liquid storage chamber.

It should be noted that the aforementioned liquid delivery component 10 is not limited to being a cold plate, but may be one of the components through which the liquid flows in a liquid cooling system.

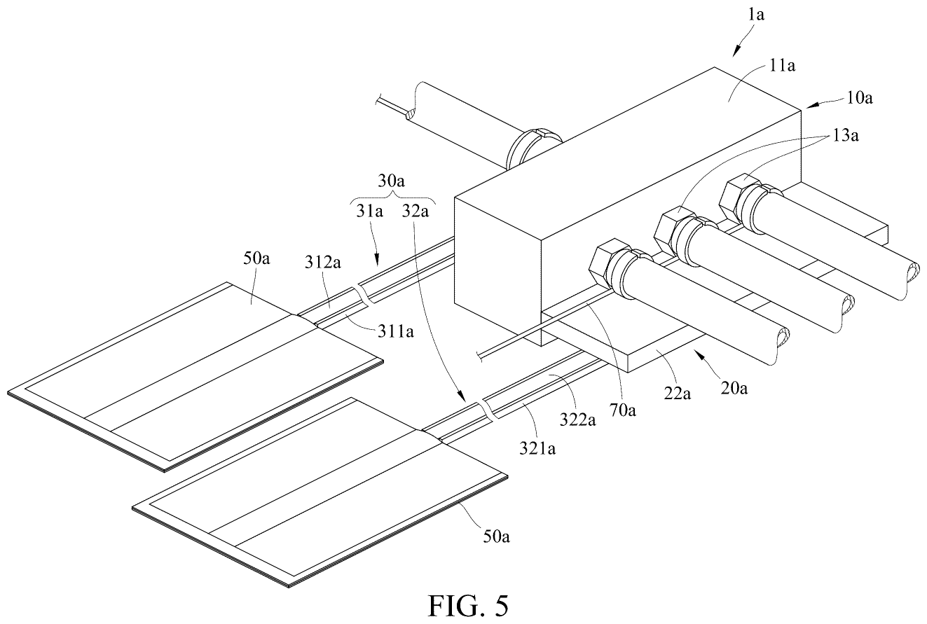

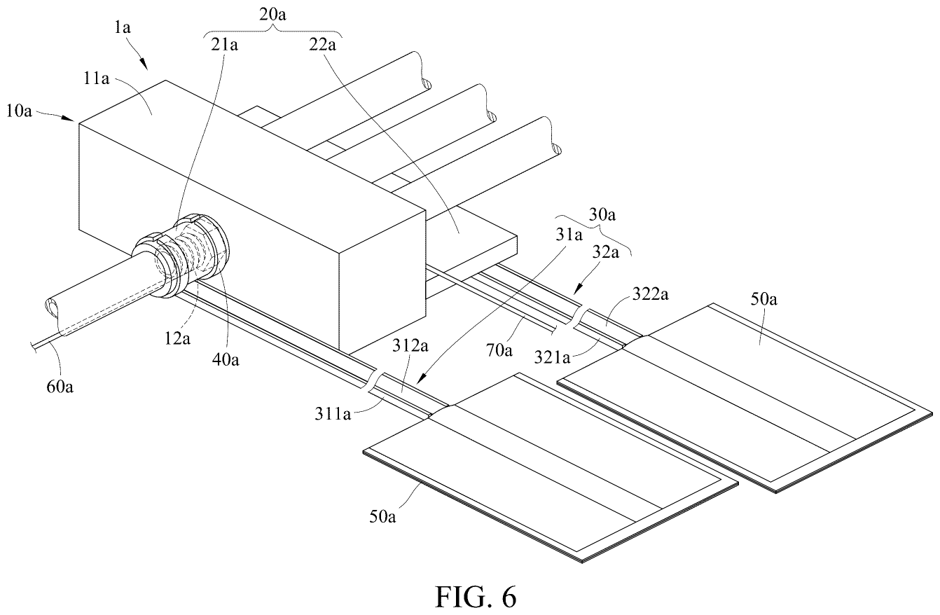

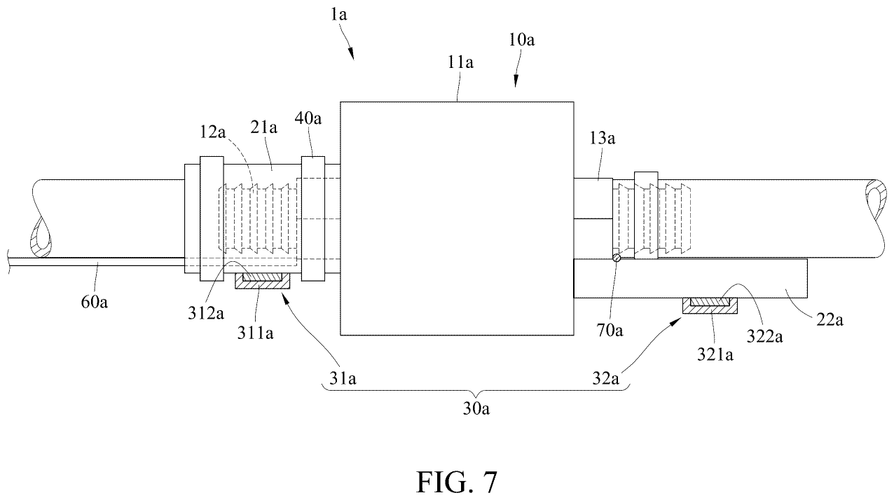

Then, referring to FIGS. 5 to 7, FIG. 5 is a perspective view of a liquid cooling assembly according to a second embodiment of the invention, FIG. 6 is another perspective view of the liquid cooling assembly in FIG. 5, and FIG. 7 is a partial cross-sectional view of the liquid cooling assembly in FIG. 5. In this embodiment, the liquid cooling assembly 1a includes a liquid delivery component 10a, a liquid absorbing component 20a and a liquid guiding component 30a.

The liquid delivery component 10a is, for example but not limited to, a manifold. The liquid delivery component 10a includes a housing 11a, an inlet joint 12a and a plurality of outlet joints 13a. The inlet joint 12a and the outlet joints 13a are disposed on two opposite sides of the housing 11a.

The liquid absorbing component 20a includes a first absorbing portion 21a and a second absorbing portion 22a. The first absorbing portion 21a and the second absorbing portion 22a are, for example, made of a liquid-absorbent and expandable material. For example, the first absorbing portion 21a and the second absorbing portion 22a may be polyvinyl alcohol foams.

The first absorbing portion 21a is disposed on the housing 11a and corresponds to the inlet joint 12a. For example, the first absorbing portion 21a is wrapped around a connection between the inlet joint 12a and the housing 11a. Additionally, the liquid cooling assembly 1a may further include a fastener 40a, which may be a buckle used to secure the first absorbing portion 21a at the connection between the inlet joint 12a and the housing 11a. The second absorbing portion 22a is disposed on the housing 11a and corresponds to the outlet joints 13a. For example, the second absorbing portion 22a is fixed to the housing 11a by adhesive, and the second absorbing portion 22a is located below the outlet joints 13a.

The liquid guiding component 30a includes a first guiding portion 31a and a second guiding portion 32a. The first guiding portion 31a is connected to the first absorbing portion 21a, and the second guiding portion 32a is connected to the second absorbing portion 22a. For example, the first guiding portion 31a includes a first water-proof casing 311a and a first liquid guiding layer 312a. The first water-proof casing 311a is, for example, a U-shaped structure, and the first water-proof casing 311a is disposed in the first absorbing portion 21a. The first liquid guiding layer 312a is, for example, a capillary structure, and the first liquid guiding layer 312a is located in the first water-proof casing 311a and contacts the first absorbing portion 21a. The second guiding portion 32a includes a second water-proof casing 321a and a second liquid guiding layer 322a. The second water-proof casing 321a is, for example, a U-shaped structure, and the second water-proof casing 321a is disposed in the second absorbing portion 22a. The second liquid guiding layer 322a is, for example, a capillary structure, and the second liquid guiding layer 322a is located in the second water-proof casing 321a and contacts the second absorbing portion 22a.

In this embodiment, the liquid cooling assembly 1a may further include two storage containers 50a, and the two storage containers 50a are respectively connected to the first guiding portion 31a and the second guiding portion 32a.

In this embodiment, the liquid cooling assembly 1 may further include a first leakage detector 60a and a second leakage detector 70a. The first leakage detector 60a and the second leakage detector 70a may, for example, be leakage detection cables. The first leakage detector 60a is partially located between the first absorbing portion 21a and the inlet joint 12a, while the second leakage detector 70a is partially located on the second absorbing portion 22a.

When leakage occurs at the inlet joint 12a and the outlet joints 13a, the first absorbing portion 21a and the second absorbing portion 22a absorb the leaked liquid. Once the liquid absorbed by the first absorbing portion 21a and second absorbing portion 22a spreads to the first liquid guiding layer 312a and the second liquid guiding layer 322a, the first liquid guiding layer 312a and the second liquid guiding layer 322a delivers the liquid to the storage containers 50a to store the liquid in the storage containers 50a.

In this embodiment, the first absorbing portion 21a of the liquid absorbing component 20a is wrapped around the connection between the inlet joint 12a and the housing 11a, the second absorbing portion 22a of the liquid absorbing component 20a is located below the outlet joints 13a, and the first guiding portion 31a and the second guiding portion 32a of the liquid guiding component 30a are respectively connected to the first absorbing portion 21a and the second absorbing portion 22a. By this configuration, the first guiding portion 31a and the second guiding portion 32a can guide and deliver the leaked liquid absorbed by the first absorbing portion 21a and the second absorbing portion 22a, allowing the first absorbing portion 21a and the second absorbing portion 22a to continue absorb the leaked liquid. As a result, the time for personnel to perform maintenance can be delayed as long as possible.

It should be noted that the first absorbing portion 21a is not limited to being wrapped around the connection between the inlet joint 12a and housing 11a. In other embodiments, the first absorbing portion may be disposed below the inlet joint, similar to the second absorbing portion.

Furthermore, the second absorbing portion 22a is not limited to being located below the outlet joints 13a. In other embodiments, the number of the second absorbing portions 22a may be multiple, and the second absorbing portions may be respectively wrapped around the outlet joints, similar to the first absorbing portion.

Furthermore, the liquid absorbing component 20a is not limited to including the first absorbing portion 21a and the second absorbing portion 22a. In other embodiments, the liquid absorbing component may include a single absorbing portion, which may be located below the inlet joint and the outlet joints. In such a case, the liquid guiding component may include a single guiding portion.

On the other hand, the first liquid guiding layer 312a of the first guiding portion 31a and the second liquid guiding layer 322a of the second guiding portion 32a are not limited to capillary structures. In other embodiments, they may simply be liquid-absorbent structures without capillary action. In such a case, the first liquid guiding layer and the second liquid guiding layer may utilize gravity to deliver the liquid.

In this embodiment, the first water-proof casing 311a of the first guiding portion 31a and the second water-proof casing 321a of the second guiding portion 32a can prevent liquid from dripping onto surrounding electronic components while the first liquid guiding layer 312a and the second liquid guiding layer 322a are delivering the liquid.

It should be noted that the structures of the first guiding portion 31a and the second guiding portion 32a are not intended to limit the invention, but may be adjusted according to actual requirements.

In this embodiment, the storage containers 50a can be placed in a suitable location either inside or outside an electronic device that includes the liquid delivery component 10a. The first guiding portion 31a and the second guiding portion 32a of the liquid guiding component 30a deliver the liquid to the storage container 50a, preventing the liquid from contacting electronic components inside the electronic device.

It should be noted that the storage containers 50a are optional components and may be omitted in other embodiments. In such case, the first guiding portion 31a and the second guiding portion 32a of the liquid guiding component may, for example, directly deliver the liquid back into the liquid cooling loop.

In this embodiment, by having the first leakage detector 60a partially between the first absorbing portion 21a and the inlet joint 12a, and the second leakage detector 70a partially on the second absorbing portion 22a, leakage at the inlet joint 12a and the outlet joints 13a can be detected. This configuration allows the leakage detectors to send a leakage signal when leakage occurs, notifying maintenance personnel.

It should be noted that the first leakage detector 60a and the second leakage detector 70a are optional components, and may be omitted in other embodiments.

It should be noted that the aforementioned liquid delivery component 10a is not limited to a manifold, but may be one of the components through which the liquid passes in a liquid cooling system.

In one embodiment of the invention, the server of the invention can be used for artificial intelligence (AI) computing, edge computing, as well as 5G server, cloud server, or vehicle-to-everything (V2X) server.

According to the liquid cooling assembly as discussed in the above embodiment, the liquid absorbing component is mounted in the liquid collecting recess of the housing and partially protrudes out of the liquid collecting recess, the liquid block cover is disposed on the housing, and the liquid block cover and the housing together enclose the liquid absorbing component. This configuration allows the liquid absorbing component, even when protruding out of the liquid collecting recess, to retain the leaked liquid, absorbed from the inlet joint or the outlet joint, in the liquid block cover. As a result, more leaked liquid can be stored, such that the time for personnel to perform maintenance can be delayed as long as possible.

On the other hand, the liquid absorbing component is disposed on the housing of the liquid delivery component and corresponds to the inlet joint and the outlet joints, and the liquid guiding component is connected to the liquid absorbing component. By this configuration, the liquid guiding component can guide and deliver the leaked liquid absorbed by the liquid absorbing component from the inlet joint or the outlet joints, allowing the liquid absorbing component to continue absorb the leaked liquid. As a result, the time for personnel to perform maintenance can be delayed as long as possible.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. A liquid cooling assembly, comprising:
a liquid delivery component, comprising a housing, an inlet joint and an outlet joint, wherein the housing comprises a liquid collecting recess, and the inlet joint and the outlet joint are disposed on the housing and at least partially located in the liquid collecting recess;
a liquid absorbing component, mounted in the liquid collecting recess of the housing and partially protruding out of the liquid collecting recess; and
a liquid block cover, disposed on the housing and enclosing the liquid absorbing component along with the housing.

2. The liquid cooling assembly according to claim 1, wherein the liquid block cover comprises an accommodation recess, the accommodation recess and the liquid collecting recess together form a liquid storage chamber, the liquid absorbing component is accommodated in the liquid storage chamber, the liquid absorbing component includes an initial state and a saturated state; when the liquid absorbing component is in the initial state, a height of the liquid absorbing component is less than a height of the liquid storage chamber; when the liquid absorbing component is in the saturated state, the height of the liquid absorbing component is equal to the height of the liquid storage chamber.

3. The liquid cooling assembly according to claim 1, wherein the liquid absorbing component comprises two avoidance recesses, and the inlet joint and the outlet joint are respectively accommodated in the two avoidance recesses.

4. A liquid cooling assembly, comprising:
a liquid delivery component, comprising a housing, an inlet joint and at least one outlet joint, wherein the inlet joint and the at least one outlet joint are disposed on the housing;
a liquid absorbing component, disposed on the housing and corresponding to the inlet joint and the at least one outlet joint; and
a liquid guiding component, connected to the liquid absorbing component.

5. The liquid cooling assembly according to claim 4, wherein the liquid delivery component is a manifold, the at least one outlet joint comprises a plurality of outlet joints, the liquid absorbing component comprises a first absorbing portion and a second absorbing portion, the first absorbing portion is disposed on the housing and corresponds to the inlet joint, the second absorbing portion is disposed on the housing and corresponds to the plurality of outlet joints, the liquid guiding component comprises a first guiding portion and a second guiding portion, the first guiding portion is connected to the first absorbing portion, and the second guiding portion is connected to the second absorbing portion.

6. The liquid cooling assembly according to claim 5, wherein the first absorbing portion is wrapped around a connection between the inlet joint and the housing, and the second absorbing portion is located below the plurality of outlet joints.

7. The liquid cooling assembly according to claim 6, further a first leakage detector and a second leakage detector, wherein the first leakage detector is partially located between the first absorbing portion and the inlet joint, and the second leakage detector is partially located on the second absorbing portion.

8. The liquid cooling assembly according to claim 5, wherein the first guiding portion comprises a first water-proof casing and a first liquid guiding layer, the first water-proof casing is disposed on the first absorbing portion, the first liquid guiding layer is located in the first water-proof casing and in contact with the first absorbing portion, the second guiding portion comprises a second water-proof casing and a second liquid guiding layer, the second water-proof casing is disposed on the second absorbing portion, and the second liquid guiding layer is located in the second water-proof casing and in contact with the second absorbing portion.

9. The liquid cooling assembly according to claim 5, further comprising two storage containers, wherein the two storage containers are respectively connected to the first guiding portion and the second guiding portion.
